(19) United States
(12) Patent Application Publication
(10) Pub. No.: US 2012/0276741 A1
(43) Pub. Date: Nov. 1, 2012

(54) BENIGN, LIQUID CHEMICAL SYSTEM-BASED BACK END OF LINE (BEOL) CLEANING

(75) Inventors: SRINI RAGHAVAN, Tucson, AZ (US); Dinesh Padmanabhan Ramalekshmi Thanu, Tucson, AZ (US); Manish K. Keswani, Tucson, AZ (US)

(73) Assignee: ARIZONA BOARD OF REGENTS ON BEHALF OF THE UNIVERSITY OF ARIZONA, TUCSON, AZ (US)

(21) Appl. No.: 13/097,181

(22) Filed: Apr. 29, 2011

(51) Int. Cl. H01L 21/306

(52) U.S. Cl. 438/689; 257/E21.228

(57) ABSTRACT

A back end of line cleaning process is performed using a liquid mixture containing at least two benign chemicals that can form a eutectic. In one embodiment, liquid mixtures of urea and choline chloride, at a molar ratio of 2:1, in the temperature range of 40° C. to 70° C. are used to remove etch residues on copper interconnects and dielectric layers created by g-line and DUV resists. In certain embodiments, eutectic, hypereutectic, and hypoeutectic compositions of the at least two benign chemicals are used.

### BACKGROUND OF THE INVENTION

As the semiconductor device industry continues to increase device performance and shrink feature sizes, copper has replaced aluminum as the interconnect material and low-k dielectrics are used as the insulator between interconnect layers. Current generation integrated circuits involve the creation of multiple copper/low-k dielectric interconnect levels, which often further include barrier and nucleation layers.

To fabricate the copper wiring in the low-k dielectric materials, a damascene process involving plasma etching of the interlayer dielectric (ILD) formed of the low-k dielectrics is used to create high aspect ratio vias and trenches. One copper interconnect fabrication process involves forming a stack of etch stop and ILD layers on a lower metal interconnect. The lower metal interconnect may include a barrier layer to protect the copper from diffusing into the dielectric. Multiple etch stop and dielectric layers can be alternatingly stacked on the lower metal interconnect, and a damascene process can be performed for via and trench patterning. For example, a resist can be deposited and patterned for a via. A plasma etching process using the patterned resist for the via as an etch mask is performed through the stack of etch stop and ILD layers until the lower metal interconnect (or an etch stop layer or a barrier layer on the lower metal interconnect) is exposed. The resist can be removed by performing an ashing process, and a second resist pattern can be formed for forming a trench including over the etched via region. The trench etching can be carried out by a plasma etching process of the dielectric layer exposed by the resist pattern for the trench. Then, the resist can be removed by performing an ashing process and the remaining etch stop layer exposed in the trench and via can be removed.

The plasma etching process typically leaves polymer-like post etch residue (PER) on the sidewall dielectrics and on underlying copper structures. The residues may occur from the plasma exposure of the low-k materials of the ILD and the etching masks, barrier layers, and/or copper or other interconnect metals.

To reduce contact resistance caused by the post etch residue and mitigate adhesion problems, the residue is removed by a back end of line (BEOL) cleaning process.

BEOL cleaning is directed to removing these post etch residues from the vias and trenches in order to achieve good adhesion and low contact resistance of the metal deposited in the high aspect ratio vias and trenches. BEOL cleaning involves wet cleaning and rinsing steps. Semi-aqueous fluoride (SAF) formulations containing between 20 to 40% of solvents and dilute hydrofluoric acid (DHF/HF) based solutions currently remain the formulations of choice for BEOL cleaning. These formulations must selectively remove the residue, which typically contains copper oxide, copper fluoride and/or fluorocarbons, without etching the sidewall dielectric and underlying copper lines. To achieve this, cleaning formulations typically contain solvents to penetrate high aspect ratio vias and trenches and swell/dissolve the residue, a fluoride source to attack Cu—O and Si—O bonds and enhance residue dissolution, water to control the activity of the fluoride component, and a corrosion inhibitor to protect copper from corrosion. Some of the commonly used solvents include Dimethyl Sulfoxide, N-Methyl Pyrrolidone, and Sulfolane.

One issue with the use of SAF solutions is that these solutions tend to generate a waste stream containing solvents and fluorides that is complex and difficult to treat. Because the environmental, safety, and health (ESH) impact of the waste created by semiconductor processing is an important consideration in maintaining and designing fabrication plants, there exists a continuous need for processes and materials that can contribute to reducing or minimizing negative ESH impact of semiconductor processing.

### BRIEF SUMMARY OF THE INVENTION

Embodiments of the present invention provide methods and materials for removing post etch residues during BEOL cleaning in semiconductor processing. Certain embodiments of the invention can improve the overall ESH impact of BEOL cleaning by using environmentally benign chemicals in place of current cleaning formulations. Accordingly, certain embodiments of the invention provide benign chemical formulations that can remove post etch residues with effectiveness at least similar to traditional cleaning formulations.

According to certain implementations, the removal of post etch residues containing copper oxide and copper fluoride created during plasma etching of dielectric materials patterned with photoresists can be accomplished using BEOL cleaning formulations containing chemicals that can form deep eutectic solvents (DES).

In one specific embodiment, a mixture of choline chloride and urea is provided that can remove post etch residues containing copper oxide and copper fluoride.

### BRIEF DESCRIPTION OF THE DRAWINGS

FIG. 1 shows a block diagram of a method of fabricating a device, including removal of a photoresist implant mask in accordance with an embodiment of the present invention.

FIGS. 2A-2E show scanning electron microscope (SEM) images over time of ˜30 nm g-line residue removal using 2:1 (urea:choline chloride) DES at 40° C. in accordance with an example embodiment of the present invention. FIG. 2A shows residue before removal (at 0 min), FIG. 2B shows residue remaining after 5 min of cleaning, FIG. 2C shows residue remaining after 10 min of cleaning, FIG. 2D shows residue remaining after 30 min of cleaning, and FIG. 2E shows residue remaining after 40 min of cleaning.

FIGS. 3A-3D show SEM images over time of ˜3 nm DUV residue removal using 2:1 (urea:choline chloride) DES at 40° C. in accordance with an example embodiment of the present invention. FIG. 3A shows residue before removal (at 0 min), FIG. 3B shows residue remaining after 5 min of cleaning, FIG. 3C shows residue remaining after 10 min of cleaning, and FIG. 3D shows residue remaining after 30 min of cleaning.

FIGS. 4A-4D show SEM images of ˜30 nm g-line residue and ˜3 nm DUV residue removal in SAF (29% DMSO+1% NH₄F+70% H₂O) and dilute HF cleaning formulations for comparison. FIG. 4A shows g-line residue remaining after 20 min of cleaning using SAF, FIG. 4B shows g-line residue remaining after 30 min of cleaning using dilute HF, FIG. 4C shows DUV residue remaining 20 min of cleaning using SAF, and FIG. 4D shows DUV residue remaining after 20 min of cleaning using dilute HF.

FIGS. 5A and 5B show a) Cu 2p and b) F 1s X-ray photoelectron spectroscopy (XPS) spectrum comparison of copper, g-line residue film, and g-line residue film cleaned in 2:1 DES at 40° C. in accordance with an embodiment of the invention.

FIG. 6 shows a plot of open circuit potential (OCP) over time of copper and residue films cleaned in 2:1 urea:choline chloride DES, 40° C.

FIG. 7 shows a plot of conductivity and viscosity of 2:1 urea:choline chloride DES at different temperatures.

FIG. 8 shows a graph illustrating the etch rate of blanket low-k dielectric (carbon doped oxide) in different cleaning formulations.

### DETAILED DISCLOSURE OF THE INVENTION

Embodiments of the invention provide an environmentally benign or a minimally environmental impacting alternative to traditional cleaning formulations used in semiconductor processing. Instead of the related art organic solvent based formulations such as SAF or dilute HF solvents, embodiments of the invention use a liquid mixture of at least two chemicals having a separate normal melting temperature higher than when combined to remove the post etch residues remaining after cleaning copper-based structures. The liquid mixture can be a deep eutectic solvent (DES); however, the composition of the at least two chemicals does not require to be at the eutectic point and can be hyper-eutectic or hypo-eutectic compositions.

A DES chemical system for a liquid mixture used in accordance with an embodiment of the invention is a low melting eutectic mixture of compounds that does not contain a traditional organic solvent in the composition, shows good conductivity, exhibits a low metal corrosion rate, and exhibits high copper oxide (and even copper fluoride) solubility. The viscosity of the subject formulations can be adjusted by mixing with suitable additives such as water. In addition, the subject DES-based formulations may exhibit low vapor pressure and a lower surface tension than water (e.g., surface tension of less than 72 mN/m).

In particular, a DES is a type of ionic liquid composed of an organic cation and an organic/inorganic anion. The DES is formed by mixing two different chemicals that can form a eutectic—a melting point lower than the melting point of the separate components (and can exist as liquid at room temperature). The DES chemical systems for the liquid mixtures used in accordance with embodiments of the invention can include formulations of the two (or more) different chemicals at eutectic, hyper-eutectic and hypo-eutectic compositions.

In accordance with certain embodiments of the invention, the at least two chemicals used to form the DES are each benign chemicals that, when combined, remain water soluble and can easily wash away with water.

In a specific embodiment of the invention, the DES is formed using choline chloride (2- hydroxyethyl-trimethylammonium chloride) (C₅H₁₄ClNO), and urea ((NH₂)₂CO). The two chemicals are heated to between 60° C. and 100° C. in order to combine, and then cooled down before use. The liquid mixture with DES of choline chloride and urea in accordance with embodiments of the invention can also include water. Choline chloride and urea form a DES because choline chloride has a melting point of 302° C. and urea has a melting point of 133° C.; however, the eutectic mixture of choline chloride and urea melts at temperatures as low as 12° C. when combined at a 2:1 mole ratio of urea to choline chloride. The ratio range can be optimized for a particular application. In certain embodiments, urea and choline chloride at a mole ratio of 1:1-4:1 can be used. With a mole ratio of 2:1, the mixture is liquid at room temperature. When higher or lower ratio of urea to choline chloride is used, the mixture will partly freeze at room temperature and will need be heated to provide a liquid mixture.

Advantageously, water can be used in order to rinse such mixtures. In various embodiments, the DES formulation can be applied to a substrate for removing the residues at a temperature of between 20° C. and 80° C. Further, in certain embodiments, DES compositions can be selected at ratios providing a liquid at temperatures up to 100° C.

Recent studies of DES solvents indicate that DES solvent properties are strongly influenced by hydrogen bonding. In addition, and the high anion concentration favors solubility of metal oxides. Accordingly, by taking advantage of these properties, embodiments of the invention provide formulations for BEOL cleaning, including removal of post-etch residues.

The subject liquid mixtures with DES formulations (including eutectic, hypereutectic, and hypoeutectic compositions of the chemicals) are capable of penetrating high aspect ratio vias and trenches to swell and/or dissolve the post etch residue from within the vias and trenches. In addition, Cu—O and. Si—O bonds can be attacked by the subject DES formulations without using a fluoride source (as in the case of conventional BEOL cleaning systems) and enhance residue dissolution. Furthermore, the subject DES formulations exhibit a low or minimal corrosion rate of copper.

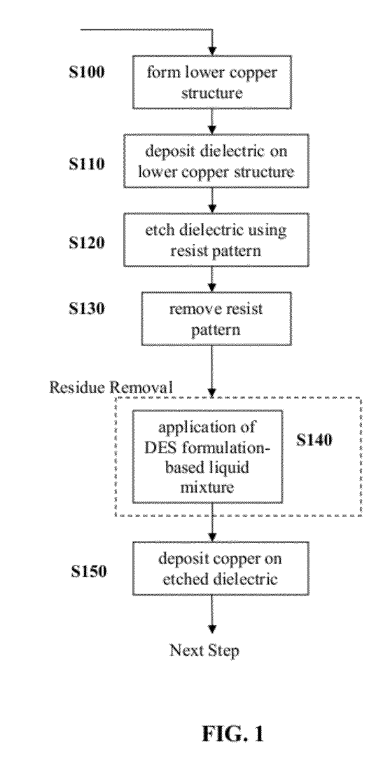

FIG. 1 shows a method of fabricating an interconnect structure in accordance with one embodiment of the invention. Referring to FIG. 1, according to one embodiment, a lower copper structure can be formed on a substrate S100. A next level interconnection can be formed on and electrically connected to the lower copper structure by, for example, performing a damascene process.

In a damascene process, a dielectric layer is patterned with open trenches (or vias) where the conductor should be located. The conductor material, including copper is then deposited in the open trenches (and/or vias). The coating of copper that overfills the trenches is removed by a chemical mechanical polishing (CMP) process such that the copper remains only within the trenches (and/or vias) to function as the patterned conductor. The damascene process can be a single damascene, where a single feature is formed and filled (e.g., a via is formed and filled and then a trench overlying a via is formed and filled), or a dual damascene, where two features are formed and filled with copper at once (e.g., a trench overlying a via is formed and then both the via and trench are filled with copper during a same deposition process). The single or dual damascene process can be performed successive times to provide a multilayer interconnection structure. Accordingly, DES solvent-based liquid mixture cleaning in accordance with embodiments of the subject invention can be applied to successive damascene processes.

For example, referring again to FIG. 1, one or more dielectric layers can be formed on the lower copper structure S110. The one or more dielectric layers can include low k dielectrics, insulating barrier films, and insulating etch-stop layers. The one or more dielectric layers can be etched to form vias and/or trenches using a resist pattern as an etch mask S120. A hard mask may also be included as part of the etch mask. The resist pattern can be formed of any suitable resist in the art for the particular feature sizes being patterned. For example, g-line resist or deep ultra violet (DUV) resist can be used depending on the photolithography source. Similarly, positive or negative resist may be used. The one or more dielectric layers may be etched using any suitable etching process. For example, an anisotropic plasma etching process such as a reactive ion etching process can be used to etch the one or more dielectric layers. The plasma etching process may include a variety of etch species, which may be adjusted as different materials are encountered during the etching process. Examples of etchants that may be used include CF₄/O₂, CF₄/Ar, CF₄/H₂, CHF₃/O₂, CH₂F₂, CHF₃, C₂F₆, C₃F₈, C₄F₈, SF), NF₃ and combinations thereof.

After performing the etching process, the resist pattern can be removed S130. In certain embodiments, such as when performing a dual damascene process, the patterning, etching, and resist removal processes S120-S130 can be repeated.

After removal of the photoresist pattern, but before filling the trenches and vias with the materials for the next level interconnection (e.g., at step S150), any residue remaining from the etching process is removed using a liquid mixture of an embodiment of the invention S140. The copper oxide, copper fluoride, and/or fluorocarbon formation resulting from the carbon and/or fluorine-based etchants are removed by using an environmentally benign liquid mixture in accordance with embodiments of the invention.

The liquid mixture can be applied to the substrate by immersion or spin processing. In one embodiment, the liquid mixture contains choline chloride and urea. In addition, water can be allowed to remain in the system and even added to the system to adjust viscosity of the liquid mixture. In a specific embodiment, choline chloride and urea at a mole ratio of 1:2 (choline chloride to urea) and a temperature in the range of 40° C.-70° C. is used. Parameters for the post-etch cleaning process, such as cleaning time, viscosity of the solution, and operating temperature, can be optimized, for example by adjusting amount of water in the solution, and the ratio of the two chemicals. Other liquid mixtures containing DES formulations (eutectic, hyper-eutectic, and hypo-eutectic) capable of cleaning etch residues including copper oxides and fluorides can also be used. For example, in another embodiment, the liquid mixture contains choline chloride and malonic acid (MA). In yet another embodiment, the liquid mixture can contain choline chloride and phenylacetic acid or phenylpropionic acid.

In one embodiment, the residue removal using an application of a DES formulation-based liquid mixture can be performed after each resist pattern removal (even in a dual damascene process). In another embodiment, the residue removal is performed only after the final patterning, etching and resist removal processes for a particular next level interconnect structure in preparation for depositing the conductive material forming the particular next level interconnect structure.

The residue removal can enable a better electrical connection with the lower copper structure by cleaning any oxide, polymer, or fluoride from the lower copper structure.

After removing the etching residues, the next level interconnection can be formed for direct electrical connection to the lower copper structure by depositing copper on the etched dielectric S150. The deposition of the copper (and any other conductive material to be provided in the trench and/or via) can be accomplished using any suitable method including electro-plating and electroless deposition processes. Barrier layers can be included to protect diffusion of the copper into the dielectric. In addition, a CMP process can be performed to establish the interconnect pattern within the vias and trenches in the dielectric. Steps S110-S150 can he repeated for each interconnect layer of a multi-level interconnect structure.

A greater understanding of the present invention and of its many advantages may be had from the following examples, given by way of illustration. The following examples are illustrative of some of the methods, applications, embodiments and variants of the present invention. They are, of course, not to be considered in any way limitative of the invention. Numerous changes and modifications can be made with respect to the invention.

To illustrate the subject DES-based liquid mixture residue removal, experiments were conducted using a copper wafer having photoresist deposited and then over-etched in a reactive ion etcher.

For the examples, porous carbon-doped silicon oxide low-k dielectric wafers of ˜2.5 k Å and electroplated copper films of ˜1.5 μm and were used. For all experiments, pre-cleaning of copper wafers was performed using isopropyl alcohol and hydrochloric acid.

### Example 1

### Removal of g-line Resist Using a DES Formulation

For the g-line photoresist studies, the residue films were prepared by spin coating the g-line photoresist on copper samples to a thickness of 1.5 μm at a spin speed of 4000 rpm for 30 seconds. The spin coated samples were then baked at 90° C. for 90 seconds. Finally, the samples were ashed in Reactive Ion Etcher (RIE) tool by introducing 40 sccm of CF₄ and 4 sccm of O₂ gases at a pressure of 50 mTorr and plasma power of 250 W. The plasma in RIE was generated with an RF (radio frequency) powered electromagnetic field. The g-line photoresist was completely ashed in eleven minutes. An additional one minute plasma etch was carried out on the copper sample after performing the ashing to form a more representative residue film.

The plasma etched residue films used in the examples were characterized for their thickness and morphology by Atomic Force Microscopy (AFM) using a Multimode IIIA Atomic Force Microscope and Scanning Electron Microscopy (SEM) using Hitachi S 4800 Field Emission Scanning Electron Microscope (FE-SEM) at a magnification of 30,000×. The thicknesses of g-line residue films were found to be ˜30 nm (standard deviation of 2 nm).

The eutectic mixture used to illustrate examples of embodiments of the invention was formed by stirring the two components, urea and choline chloride, at a 2:1 molar ratio and heating to 100° C. until a homogeneous, colorless liquid was formed. This DES formulation was used at room temperature (20° C.), 40° C. and 70° C. to clean the residues. Following cleaning, the samples were rinsed with DI water and the residue removal was characterized using SEM. In the experiments, it was found that cleaning at room temperature results in incomplete film removal, even after 60 minutes. However, when the temperature of the eutectic mixture was increased to 40° C., the g-line residue film appears to be removed from the copper surface.

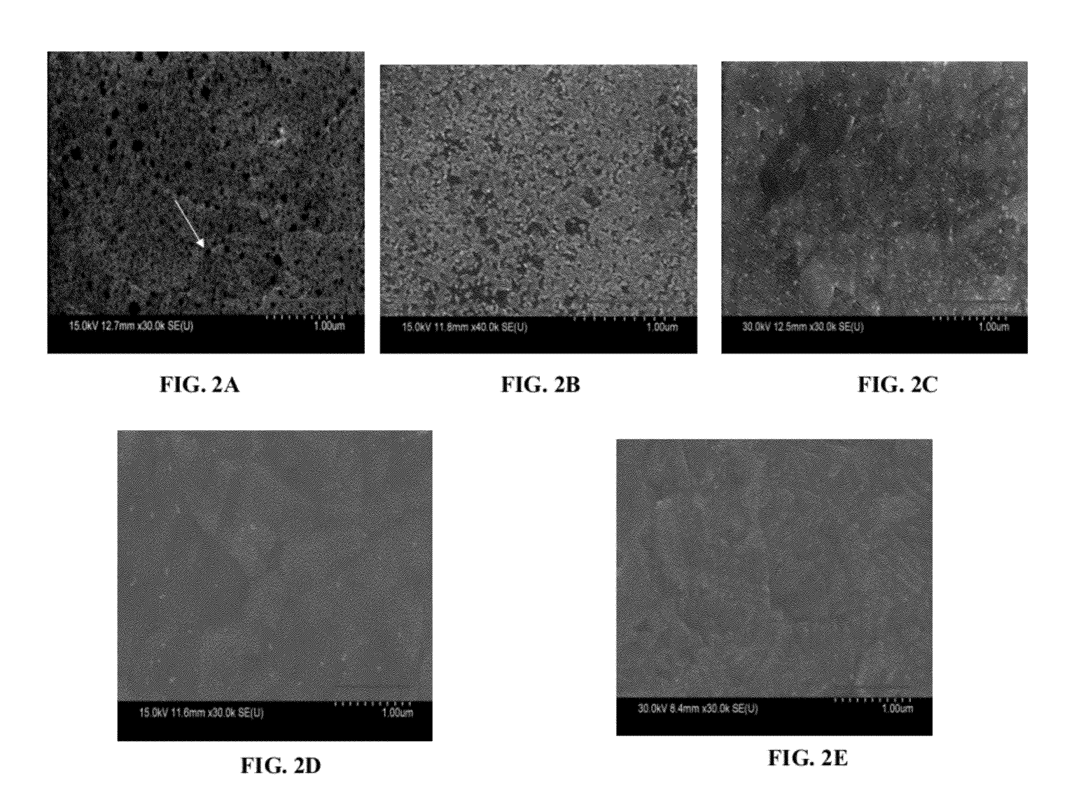

Residue film removal at 40° C. monitored at different times is shown as an example in FIGS. 2A-2E, which illustrate the morphology of the residue films. In particular, FIGS. 2A-2E show SEM images over time of ˜30 nm g-line residue removal using 2:1 (urea:choline chloride) DES at 40° C. in accordance with an example embodiment of the present invention. FIG. 2A shows residue before removal (at 0 min), FIG. 2B shows residue remaining after 5 min of cleaning, FIG. 2C shows residue remaining after 10 min of cleaning, FIG. 2D shows residue remaining after 30 min of cleaning, and FIG. 2E shows residue remaining after 40 min of cleaning. The SEM images show the presence of a number of defects in the form of pores and cracks. Complete removal of g-line residue film was observed in 40 minutes at 40° C. (as illustrated by FIG. 2D) and 30 minutes at 70° C.

### Example 2

### Removal of DUV Resist Using a DES Formulation

For the DUV photoresist studies, the residue films were prepared by spin coating the DUV photoresist on copper samples to a thickness of 0.5 μm at a spin speed of 4000 rpm for 30 seconds. The spin coated samples were then baked at 90° C. for 90 seconds. Finally, the samples were ashed in a RIE tool by introducing 40 sccm of CF₄ and 4 sccm of O₂ gases at 50 mTorr pressure and 250 W of plasma power. The plasma in RIE was generated with an RF powered electromagnetic field. The DUV was ashed in seven minutes. Then, to form a more representative residue film, the exposed copper was plasma treated for one additional minute. Using AFM and SEM, the thickness of DUV residue films were found to be ˜3 nm (standard deviation of 1 nm).

The eutectic mixture used to illustrate examples of embodiments of the invention was formed by stirring the two components, urea and choline chloride, at a 2:1 molar ratio and heating to 100° C. until a homogeneous, colorless liquid was formed. This DES formulation was used at room temperature (20° C.), 40° C. and 70° C. to clean the residues. Following cleaning, the samples were rinsed with DI water and the residue removal was characterized using SEM using the Hitachi S 4800 FE-SEM. In the experiments, it was found that cleaning at room temperature results in incomplete film removal, even after 60 minutes.

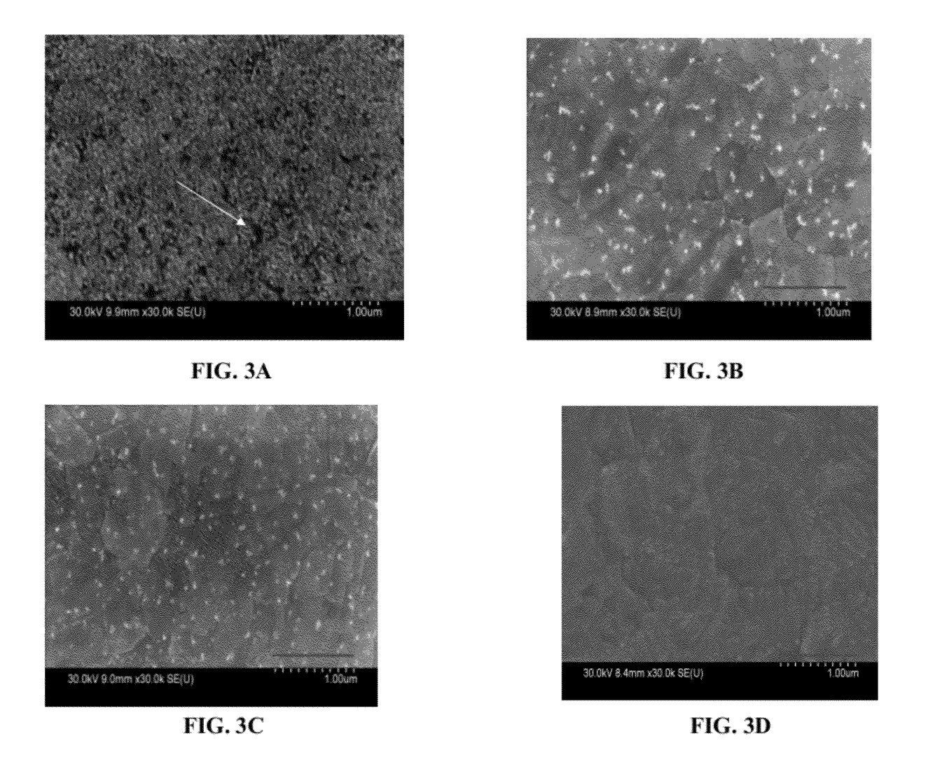

However, similarly to the g-line experiments, when the temperature of the eutectic mixture was increased to 40° C., the DUV residue film appears to be removed from the copper surface, as illustrated by FIGS. 3A-3D, which show SEM images over time of ˜3 nm DUV residue removal using 2:1 (urea:choline chloride) DES at 40° C. in accordance with an example embodiment of the present invention. FIG. 3A shows residue before removal (at 0 min), FIG. 3B shows residue remaining after 5 min, FIG. 3C shows residue remaining after 10 min, and FIG. 3D shows residue remaining after 30 min. The SEM images show the presence of a number of defects in the form of pores and cracks. Complete removal of DUV residue film was achieved in 30 minutes at 40° C. (as illustrated by FIG. 3D) and 20 minutes at 70° C.

### Example 3

### Conventional Processes for Residue Removal

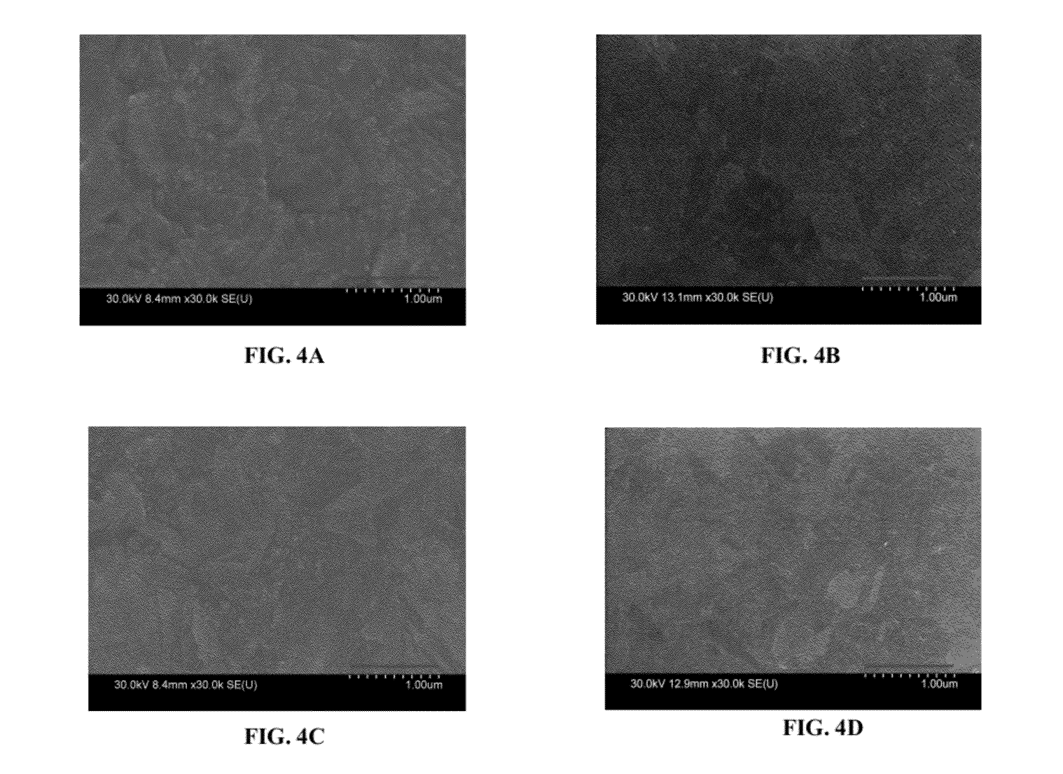

Conventional semi-aqueous fluoride (SAF) and dilute HF cleaning formulations were used to remove g-line and DUV residues, as shown in FIGS. 4A-4D, which show SEM images of ˜30 nm g-line residue and ˜3 nm DUV residue removal in SAF (29% DMSO+1% NH₄F+70% H₂O) and dilute HF cleaning formulations for comparison with the DES formulation of an embodiment of the invention. FIG. 4A shows g-line residue remaining after 20 min of cleaning using SAF, FIG. 4B shows g-line residue remaining after 30 min of cleaning using dilute HF, FIG. 4C shows DUV residue remaining after 20 min of cleaning using SAF, and FIG. 4D shows DUV residue remaining after 20 min of cleaning using dilute HF. As illustrated in the Figures, the SAF formulations remove the g-line residue film completely in 20 minutes whereas dilute HF removes the film in 30 minutes. In addition, the DUV residue films were removed completely by SAF and dilute HF solutions in 20 minutes. Accordingly, the removal rates illustrated by FIGS. 2A-2D and 3A-3D are comparable to the residue removal rates using conventional solutions.

### Example 4

### Confirmation of Residue Removal in DES Formulations

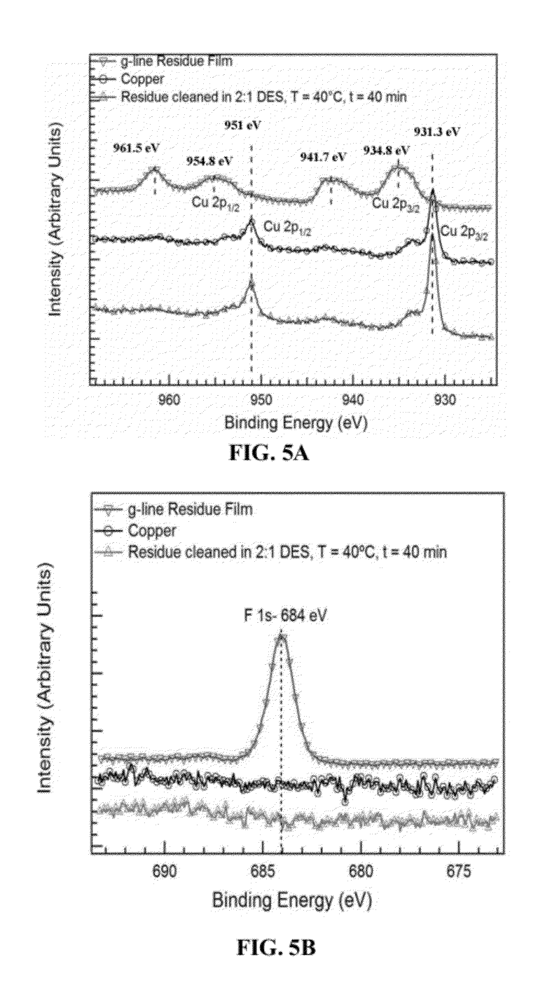

Additional evidence for residue removal in DES was obtained using techniques of X-ray photoelectron spectroscopy (XPS) and open circuit potential (OCP) measurements. The XPS system consisted of a monochromatic Al kα X-ray source and a hemispherical mirror analyzer (Kratos 165). FIGS. 5A and 5B compare the Cu2p (FIG. 5A) and F1s (FIG. 5B) spectrum of the copper sample, the g-line residue film and g-line cleaned in 2:1 DES at 40° C. Referring to FIG. 5A, bare copper shows a Cu 2p_{1/2} peak at a binding energy of 951 eV and a Cu 2p_{3/2} peak at a binding energy of 931.3 eV. Referring to FIG. 5B, no fluorine peak for the copper was seen in the spectrum. For the residue film, the Cu 2p_{1/2} peak is observed at a binding energy of 955 eV and the Cu 2p_{3/2} peak is observed at a binding energy of 935 eV. These binding energies correspond to the +2 oxidation state of copper. As shown in FIG. 5A, in addition to the major peaks, characteristic shakeup satellites at binding energies of 961.5 eV and 941.7 eV were also observed for the g-line residue film. The “shake up satellite” is believed to represent the valence-electron configuration of the ground state. As shown in FIG. 5B, the fluorine peak for the g-line residue film was observed at 684 eV. After the residue film was cleaned in 2:1 DES at 40° C. for 40 min, the Cu 2p spectrum looks identical to that of bare copper and no fluorine peak was observed, which indicates complete removal of the residue film.

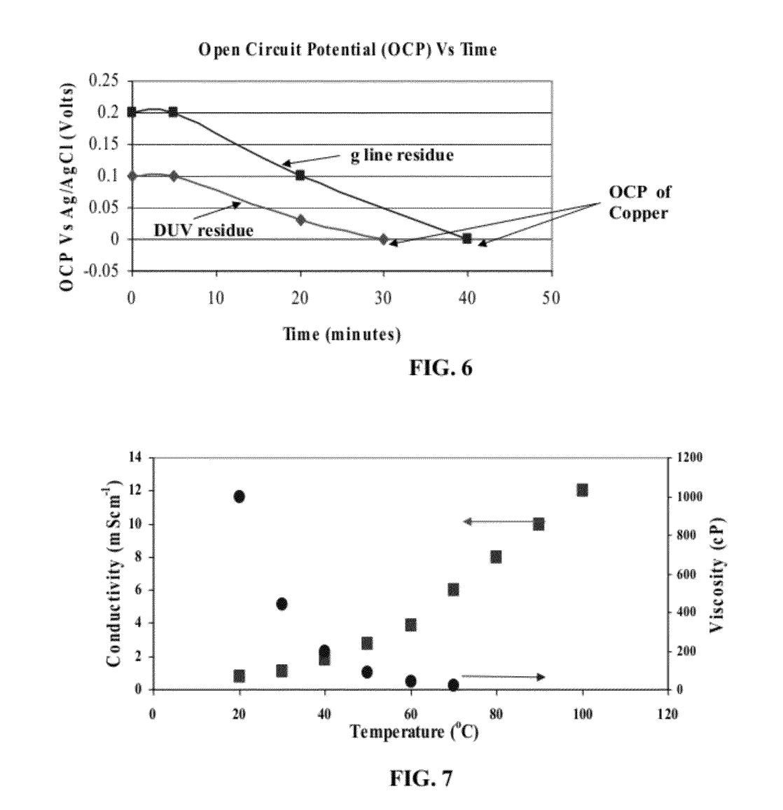

Further confirmation of the residue removal was obtained by monitoring over time open circuit potential (OCP) of bare copper, copper covered with residue film, and residue coated copper cleaned in DES at 40° C. The measured values are shown in FIG. 6. For the electrochemical measurements, 0.1 M H₂SO₄ was used as the electrolyte. Copper has an OCP of −0.01V, whereas g-line and DUV residue films have an OCP of 0.2V and 0.1V, respectively. Referring to FIG. 6, when the g-line and DUV residue films were cleaned in 2:1 DES for 5 minutes, the measured OCP is identical to that of residue film, indicating incomplete removal. But when the g-line residue samples were cleaned for 40 min and the DUV residue samples were cleaned for 30 min, it can be seen that they have the OCP of bare copper, which confirms complete removal.

### Example 5

### Characteristics of DES Formulation According to Temperature

FIG. 7 shows the conductivity (squares) and viscosity (circles) of 2:1 urea:choline chloride DES at different temperatures. For conductivity measurements, an Orion epoxy body graphite electrode with built-in thermistor for automatic temperature compensation was used. Viscosity was determined using a Brookfield viscometer. As shown in FIG. 7, conductivity of ˜1 mScm⁻¹ was measured at 20° C., which is comparable to 1 mM KCl, and the conductivity of the DES system increases with an increase in temperature. The DES system is characterized with a high viscosity (˜1000 cP) at room temperature, but an increase of temperature significantly decreases the viscosity. Although not shown in the plot, the addition of water to the system decreases the viscosity for a given temperature without significantly impacting the conductivity. Therefore, in certain embodiments, water can be added to the system when performing the BEOL cleaning process.

The surface tension of solutions at different temperatures was measured by Wilhelmy plate technique using Calm DCA 312 dynamic contact angle analyzer. The surface tension was measured to be ˜50 dynes/cm in the temperature range of 20 to 70° C.

### Example 6

### Selectivity

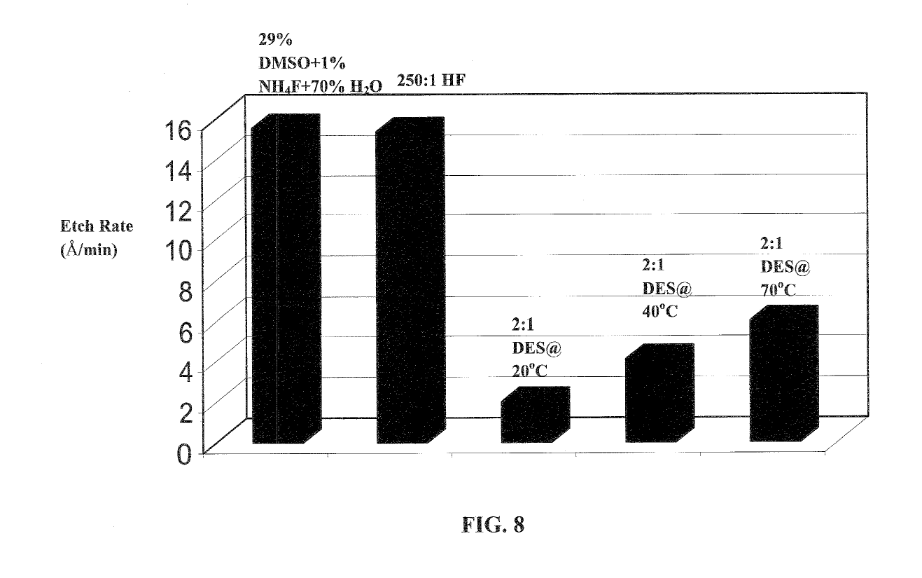

A residue cleaning formulation should be able to selectively remove the post etch residues without attacking the sidewall dielectrics. This can be shown by testing whether a cleaning formulation has a low etch rate when etching the materials that are used for interlayer dielectrics. The DES system of 2:1 urea to choline chloride and conventional systems was tested to show its relative selectivity. To provide a comparison of the etch rate of a low-k dielectric, a blanket porous low-k dielectric of a carbon doped oxide was etched in different cleaning formulations and the etch rate was determined using ellipsometry. Here, the removal rate of the carbon doped oxide was measured using a Gaertner ellipsometer. The results of the measurements are shown in FIG. 8. Referring to FIG. 8, it can be seen that 2:1 DES etches low-k dielectric at a rate (˜2 Å/min at 25° C., ˜4 Å/min at 40° C. and −6 Å/min at 70° C.) much smaller than conventional cleaning formulations (˜16 Å/min).

Accordingly, a DES containing mixture of urea and choline chloride at a molar ratio of 2:1 shows suitable removal of post etch residue films prepared from g-line and DUV photoresists.

As illustrated in the examples, a DES containing eutectic mixture of two benign chemicals, choline chloride and urea in the temperature range of 40° C. to 70° C. removes the post etch residues as effective as SAF and dilute HF cleaning solutions. Moreover, the example formulations provide a low etch rate of low- k materials compared to the conventional formulations. Thus, in certain embodiments, improvement in the overall ESH impact of BEOL cleaning can be achieved by using DES formulations for reside removal.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. In addition, any elements or limitations of any invention or embodiment thereof disclosed herein can be combined with any and/or all other elements or limitations (individually or in any combination) or any other invention or embodiment thereof disclosed herein, and all such combinations are contemplated with the scope of the invention without limitation thereto.

It should be understood that the examples and embodiments described herein are for illustrative purposes only and that various modifications or changes in light thereof will be suggested to persons skilled in the art and are to be included within the spirit and purview of this application.

1. A method of performing a back end of line (BEOL) cleaning process, the method comprising:
removing a resist pattern after etching a dielectric layer to expose an underlying metal interconnection; and
applying a liquid mixture of at least two chemicals to remove residues remaining after removing the resist pattern, wherein the melting point of the liquid mixture is lower than the melting point of each of the at least two chemicals.

2. The method according to claim 1, wherein the liquid mixture comprises a deep eutectic solvent at a eutectic composition.

3. The method according to claim 1, wherein the underlying metal interconnection comprises copper and the liquid mixture comprises urea and choline chloride.

4. The method according to claim 3, wherein applying the liquid mixture to remove residues remaining after removing the resist pattern comprises:
applying a 2:1 mole ratio mixture of urea and choline chloride at a temperature of 20° C.-70° C.

5. The method according to claim 1, wherein the liquid mixture comprises choline chloride and malonic acid.

6. The method according to claim 1, wherein the liquid mixture further comprises water.

7. The method according to claim 6, wherein applying the liquid mixture to remove residues remaining after removing the resist pattern comprises:
adding the water to the liquid mixture to adjust viscosity of the liquid mixture.

8. The method according to claim 6, wherein the at least two chemicals of the liquid mixture comprise urea and choline chloride.

9. The method according to claim 8, wherein the mole ratio of urea to choline chloride is 1:1-4:1.

10. The method according to claim 6, wherein the at least two chemicals of the liquid mixture comprise choline chloride and malonic acid.

11. The method according to claim 1, wherein applying the liquid mixture to remove residues remaining after removing the resist pattern comprises applying the liquid mixture of the at least two chemicals at a temperature of up to 100° C.

12. The method according to claim 11, wherein the liquid mixture comprises a eutectic formulation of the at least two chemicals.

13. The method according to claim 1, wherein applying the liquid mixture to remove residues remaining after removing the resist pattern comprises applying the liquid mixture of the at least two chemicals at a temperature of up to 80° C.

14. The method according to claim 1, wherein the liquid mixture comprises a hypereutectic or hypoeutectic formulation of the at least two chemicals.
